(19) United States
(12) Patent Application Publication
(10) Pub. No.: US 2006/0144823 A1
(43) Pub. Date: Jul. 6, 2006

(54) Etching solution for D-defect evaluation in silicon wafer and evaluation method using the same

(76) Inventors: Young-Hun Kim, Kumi-si (KR); Sung-Wook Lee, Kumi-si (KR); Young-Chang Park, Kumi-si (KR)

Correspondence Address: CHRISTIE, PARKER & HALE, LLP, PO BOX 7068, PASADENA, CA, 91109-7068, US

(21) Appl. No.: 11/323,907

(22) Filed: Dec. 29, 2005

(30) Foreign Application Priority Data
Dec. 30, 2004 (KR) 10-2004-0117424
Dec. 30, 2004 (KR) 10-2004-0117394

(51) Int. Cl. C23F 1/00; C03C 15/00; B44C 1/22; H01L 21/66

(52) U.S. Cl. 216/85; 216/84; 438/14

(57) ABSTRACT

The present invention relates to an etching solution for evaluating crystal defects of silicon wafers, and more particularly to an etching solution comprising KMnO₄ and HF. The etching solution for crystal defect evaluation of a silicon wafer in accordance with the present invention can accurately and quickly evaluate the crystal defects in silicon wafers having specific resistance values of 0.01 Ω·cm or smaller, which previously could only be evaluated by physical methods. Also, the etching solution of the present invention can quickly evaluate a D-defects in silicon wafers having specific resistance values exceeding 0.01 Ω·cm.

### CROSS-REFERENCE TO RELATED APPLICATIONS

This application claims priority to and the benefit of Korean Patent Application Nos. 10-2004-0117424 and 10-2004-0117394, both filed on Dec. 30, 2004 in the Korean Intellectual Property Office, the entire disclosures of which are incorporated herein by reference.

### FIELD OF THE INVENTION

The present invention relates to an etching solution for crystal defect evaluation in a silicon wafer, and more particularly to an etching solution for D-defect evaluation in a silicon wafer comprising KMnO₄ and HF, and an evaluation method using the same.

### BACKGROUND OF THE INVENTION

As semiconductor circuits become smaller and more integrated, the requirements of silicon single crystals used as substrate materials become more stringent. In general, a wafer has the following crystal defects—COP (crystal originated particles), FPD (flow pattern defects), OISF (oxide induced stacking faults), BMD (bulk micro-defects), LSTD (laser scattering tomography defects)—from the center of the wafer outward. Reducing the density and size of these growth-related defects, which negatively affect yield and quality is necessary. Thus, a technique for enabling complete removal and quick and easy evaluation of crystal defects is very important.

COP refers to particles having octahedron-shaped voids resulting from supersaturation of point defects formed in silicon single crystals during crystal growth. This defect is also called a D-defect. A lot of effort is being expended to minimize COP, which is inevitably involved in the growth of silicon single crystals. Also, a lot of techniques for evaluating the crystal defects are being developed.

A method is known for surfacing defects by selective wet etching and observing them using a microscope to evaluate the crystal defects of a wafer. Control of microdefects in silicon wafers has become a very important current technical challenge. In crystal defect evaluation of a silicon wafer by selective etching, an etching solution containing hexavalent chromium has been widely used. However, the regulation of hexavalent chromium, which is an environmentally harmful substance, has led to the development of alternative etching solutions. The wet etching method is applicable only to silicon wafers having specific resistance values larger than 0.01 Ω·cm. That is, surfacing of crystal defects cannot be performed by the wet etching method for silicon wafers having specific resistance values of 0.01 Ω·cm or smaller.

The following physical methods have been employed to evaluate D-defects of silicon wafers having specific resistance values of 0.01 Ω·cm or smaller. First, the COP distribution of a polished and washed wafer has been evaluated using a particle counter. Second, oxide precipitate has been formed by heat treatment at high temperature, and the defect regions divided through XRT evaluation, in which precipitation behaviors of different defect regions are compared. Third, a wafer has been etched for a long time with an SC-1 solution and the D-defect regions divided using a scanning surface inspection system (SSIS) (ECS (Crystal Defects in Highly Boron Doped Silicon) vol. 144(11), 1997).

The first evaluation method requires that the polished and washed wafer be very clean. Thus, several processes are required after the growth of a single crystal, which increases processing time. Also, an expensive particle counter is needed for evaluation. The second evaluation method is disadvantageous in that a long time is required for evaluation, high expense is incurred in heat treatment at a high temperature, and expensive equipment must be used. The third method requires a lot of time and expense due to long (about 4 hours) SC-1 etching time and additional required equipment.

A method of evaluating crystal defects in silicon wafers having specific resistance values exceeding 0.01 Ω·cm, including surfacing defects by selective wet etching and observing them using a microscope is known. Typically, a mixture of an oxidant and hydrofluoric acid is used in the wet etching, which comprises oxidation of silicon by the oxidant and dissolution of silicon oxide by the hydrofluoric acid. Selective etchants used for evaluation of crystal defects are disclosed in Japanese Patent Laid-Open No. 2002-236081 and listed in Table 1 below.

TABLE 1

| Etching | | | |
|---|---|---|---|
| solution | Composition | Etching rate | Remarks |
| Dash | HF, HNO₃, CH₃COOH | ˜0.2 μm/min | Very low etching rate. |
| | (1:3:12) | | |
| Sirtle | HF, Cr, H₂O | ˜1 μm/min | |
| | (1:0.4:0.2) | | |
| Secco | HF, K₂Cr₂O₇ solution (0.15 mol %) | ˜1.2 μm/min | Dislocation is observed |
| | (2:1) | | after Secco etching and |
| | | | heat treatment. |
| Wright | HF, HNO₃, CrO₃ solution (5 mol %). | ˜1 μm/min | |
| | Cu(NO3)₂, CH₃COOH, H₂O | | |

As seen in Table 1, the Dash etching solution uses nitric acid as an oxidant and does not contain hexavalent chromium. Instead, it comprises HF, HNO₃, and CH₃COOH in a volume ratio of 1:3:12, and is capable of detecting defects without regard to the planar orientation of the crystal. However, because the solution has a low etching rate, a long etching time (about 30 minutes) is required. The Sirtle etching solution is restricted in that it is not applicable to all crystal faces. The Secco etching solution has a high etching rate but supersonification is required because foam tends to generate. The Wright etching solution is widely used because of its good etching rate and wide applicability.

If a silicon wafer is etched with the Secco etching solution for a long time (30 minutes) without supersonification, FPD, one of the important D-defects, is observed. Thus, density and distribution of D-defects in a silicon wafer can be evaluated relatively easily and quickly without expensive equipment. However, the Sirtle etching solution, the Wright etching solution, and the Secco etching solution use hexavalent chromium as an oxidant. As noted above, hexavalent chromium is a regulated, environmentally harmful substance. Therefore, development of alternative etching solutions is needed.

Specifically, an etching solution that is not environmentally harmful, that has no hexavalent chromium, and that enables simple, inexpensive, effective, and quick evaluation of D-defects in silicon wafers having low or high specific resistance values is needed.

### SUMMARY OF THE INVENTION

In one embodiment of the present invention, an etching solution is provided that is applicable to silicon wafers having specific resistance values of 0.01 Ω·cm or smaller, that can be evaluated by only a physical method without the need for conventional wet etching solutions, and that enables inexpensive, simple, and quick evaluation of crystal defects in silicon wafers.

In another embodiment of the present invention, an etching solution is provided that does not contain hexavalent chromium, that is not harmful to the environment, that is applicable to silicon wafers having specific resistance values exceeding 0.01 Ω·cm, and that enables simple and quick evaluation of D-defects in silicon wafers.

In still another embodiment of the present invention, an inexpensive, simple, and quick evaluation method of crystal defects in a silicon wafer is provided that reduces environmental pollution by using a solution that does not contain hexavalent chromium.

In one embodiment of the present invention, an etching solution for evaluating D-defects in silicon wafers comprises KMnO₄, HF, and water.

In another embodiment of the present invention, an etching solution is provided for evaluating crystal defects of silicon wafers having specific resistance values in the range of 0.005 Ω·cm to 0.01 Ω·cm. In yet another embodiment of the present invention, an etching solution is provided for evaluating crystal defects of silicon wafers having specific resistance values in the range of 0.01 Ω·cm to 25.0 Ω·cm.

In still another embodiment of the present invention, a method of evaluating crystal defects in silicon wafers includes surfacing the crystal defects by treating the silicon wafers with said etching solution, and evaluating them using a microscope.

The method of evaluating crystal defects in accordance with the present invention, in which said etching solution containing KMnO₄ is used, applies both to silicon wafers having specific resistance values in the range of 0.005 Ω·cm to 0.01 Ω·cm and in the range of 0.01 Ω·cm to 25.0 Ω·cm.

### BRIEF DESCRIPTION OF THE DRAWINGS

FIG. 1 is a photograph showing the surface of a silicon wafer treated as in Example 1.

FIG. 2 is a photograph showing the surface of a silicon wafer treated as in Comparative Example 1.

FIG. 3 is a comparison of the defect regions inside a wafer treated as in Comparative Example 2.

FIG. 4a is a photograph showing a surface defect (FPD: flow pattern defect) of a silicon wafer treated as in Example 2.

FIG. 4b is a graph of the relationship between FPD and density of the silicon wafers treated as in Example 2 and Comparative Example 3 (Secco etchant).

FIG. 5a is a photograph showing a defect (FPD) of a silicon wafer treated as in Comparative Example 3 (Secco etchant).

FIG. 5b is a graph of the relationship between FPD and the FPD defect region of silicon wafers treated as in Example 2 and Comparative Example 3 (Secco etchant).

FIG. 6 is a photograph showing a silicon wafer evaluated as in Example 3.

### DETAILED DESCRIPTION OF THE PREFERRED EMBODIMENTS

In one embodiment of the present invention, an etching solution is provided for evaluating crystal defects of a silicon single crystal, which is grown by the CZ Czochralski) or FZ (Float Zone) method, and is applicable to silicon wafers having specific resistance values of 0.01 Ω·cm or smaller, for example in the range of 0.005 Ω·cm to 0.01 Ω·cm. The etching solution is also applicable to silicon wafers having specific resistance values exceeding 0.01 Ω·cm, for example in the range of 0.01 to 25.0 Ω·cm.

An example of a silicon wafer having a specific resistance value of 0.01 Ω·cm or smaller is a heavily boron doped silicon wafer in which boron is doped into the silicon single crystal to a concentration of at least 8.5×10¹⁸ atoms/cm³. As described above, a silicon wafer having a specific resistance value of 0.01 Ω·cm or smaller cannot be etched with conventional wet etching solutions, and a physical process using expensive equipment must be used or several treatment processes must be performed for crystal defect evaluation. The etching solution of the present invention is advantageous in that crystal defects can be evaluated simply and effectively, even for silicon wafers having specific resistance values of 0.01 Ω·cm or smaller. Also, the etching solution of the present invention can be used to quickly evaluate D-defects, which was previously only possible with an etching solution containing chromium.

In one embodiment, the etching solution comprises KMnO₄, HF, and water, the volume ratio of KMnO₄ to HF ranging from 0.5:1 to 1:3. The concentration of said constituents is determined considering the possibility of defect evaluation, etching time, and effectiveness. For example, for a silicon wafer having a specific resistance value of 0.01 Ω·cm or smaller, 0.3 M to 0.5 M KMnO₄ and 50% HF may be used. If the concentration of KMnO₄ is below 0.3 M, reaction time may be extended, and productivity may decrease. In contrast, if the concentration of KMnO₄ exceeds 0.5 M, the reaction proceeds abruptly, making the evaluation of crystal defects difficult. In addition, for a silicon wafer having a specific resistance value exceeding 0.01 Ω·cm, 0.4 to 0.5 M KMnO₄ and 50% HF may be used. If the concentration of KMnO₄ is too low, reaction time may increase and productivity may decrease. In contrast, if the concentration is too high, the reaction proceeds abruptly, and evaluation of crystal defects becomes difficult.

In another embodiment of the present invention, a method is provided for evaluating D-defects in silicon wafers having specific resistance values of 0.01 Ω·cm or smaller, for example ranging from 0.005 Ω·cm to 0.01 Ω·cm. In yet another embodiment of the present invention, a method is provided for evaluating D-defects in silicon wafers having specific resistance values exceeding 0.01 Ω·cm, for example ranging from 0.01 to 25.0 Ω·cm. In an embodiment of the present invention, the wafer treated with said etching solution may be rinsed with pure water. Evaluation of the crystal defects using a microscope may be performed by known methods. For example, after positioning the defects using an optical microscope, defect density may be determined through automatic counting.

A silicon wafer having a specific resistance value of 0.01 Ω·cm or smaller may be treated with the etching solution for 20 to 60 seconds at normal temperature and normal pressure (1 atm).

A silicon wafer having a specific resistance value exceeding 0.01 Ω·cm may be treated with the etching solution for 45 to 90 seconds at normal temperature and normal pressure (1 atm).

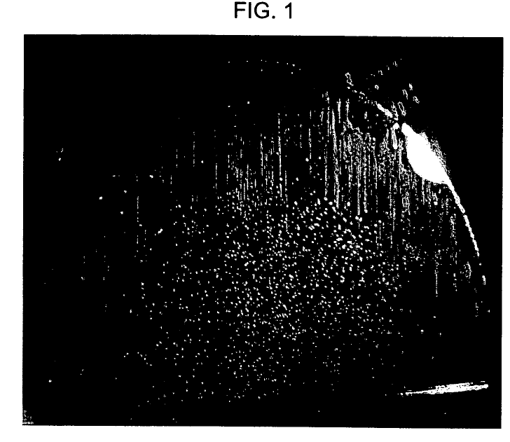

FIG. 1 is a photograph showing the surface of a silicon wafer having a specific resistance value of 0.01 Ω·cm or smaller after treatment with an etching solution of the present invention. Crystal defects are shown in the figure.

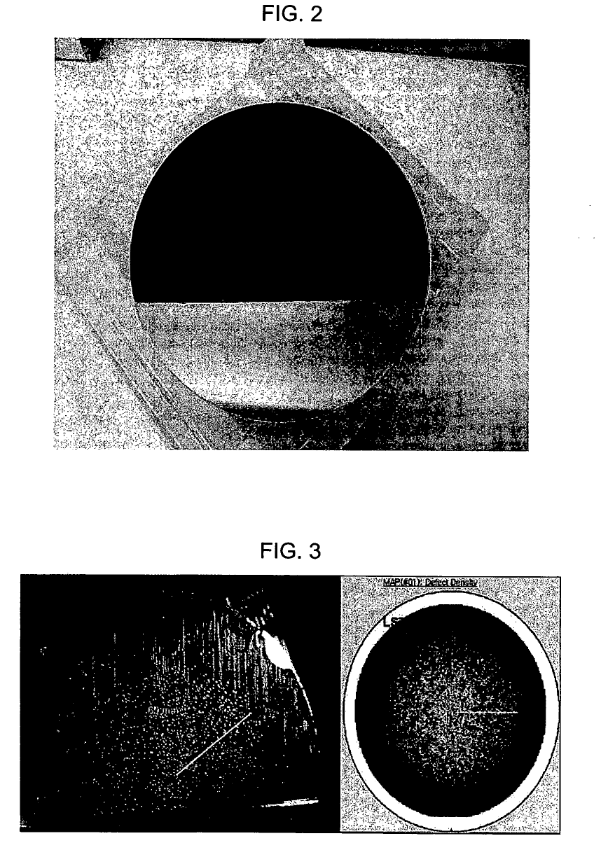

FIG. 2 is a photograph showing the surface of a silicon wafer treated with the Secco etching solution for comparison with the present invention. It can be seen that surface observation is very difficult for a silicon wafer having a specific resistance value of 0.01 Ω·cm or smaller because of the abrupt reaction.

FIG. 3 shows the defect region in the wafer of FIG. 1 determined by the LSTD method. It shows the same result as the evaluation method using the etching solution of the present invention.

Hereinafter, the present invention will be described in more detail through the following examples. However, these examples are provided to better understand the present invention and are not to be construed as limiting the scope of the present invention.

### EXAMPLES

### Example 1

### Crystal Defect Evaluation Using an Etching Solution of the Present Invention

A silicon wafer was prepared from a single crystal having a boron concentration of 5.7×10¹⁸ atoms/cm³, which was grown by the Czochralski method.

An etching solution of the present invention was prepared by mixing 3340 mL of 50% HF, 0.4 M KMnO₄, and 1650 mL of H₂O. The silicon wafer was treated with the etching solution at normal temperature and 1 atm for 30 seconds, without stirring. The surface of the silicon wafer is shown in FIG. 1.

### Comparative Example 1

### Crystal Defect Evaluation Using Secco Etching Solution

A silicon wafer was treated as in Example 1, except that a Secco etching solution (1:2 mixture of K₂Cr₂O₇ (0.15 M) solution and HF) was used instead of an etching solution of the present invention. The surface of the silicon wafer is shown in FIG. 2.

As seen in FIG. 2, surface observation of the wafer was very difficult for the silicon wafer (which was heavily doped with boron) using the Secco etching solution because of the abrupt reaction.

### Comparative Example 2

### Crystal Defect Evaluation by LSTD

A crystal defect region of the silicon wafer of Example 1 was observed by the LSTD method for comparison with an evaluation in accordance with the present invention. The results are shown in FIG. 3.

### Example 2

### Crystal Defect Evaluation Using an Etching Solution of the Present Invention

A silicon wafer was prepared from a single crystal having a specific resistance value of 5.0 Ω·cm, which was grown by the Czochralski method.

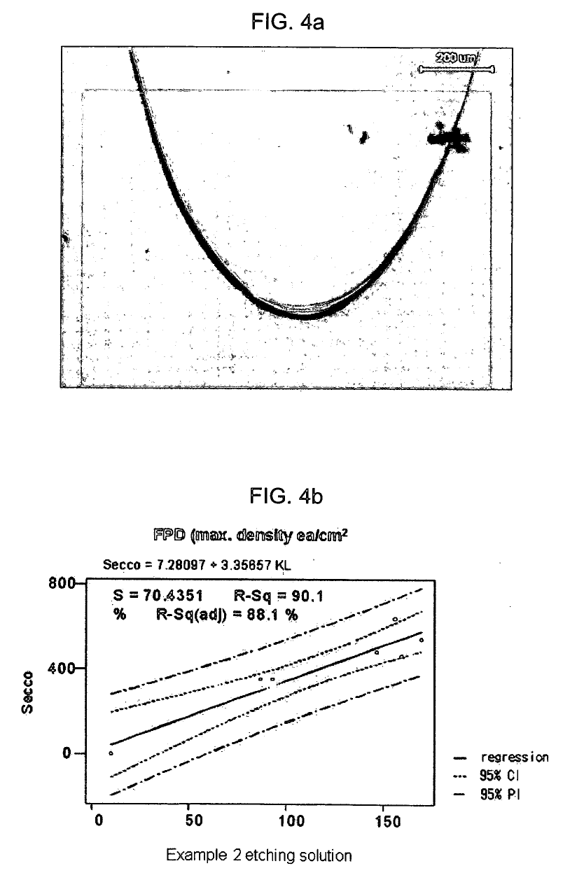

An etching solution of the present invention was prepared by mixing 3340 mL of 50% HF, 0.4 M KMnO₄, and 1650 mL of H₂O. The silicon wafer was treated with the etching solution at normal temperature and 1 atm for 60 seconds, without stirring. FPD of the silicon wafer is shown in FIG. 4a.

### Comparative Example 3

### Crystal Defect Evaluation Using the Secco Etching Solution

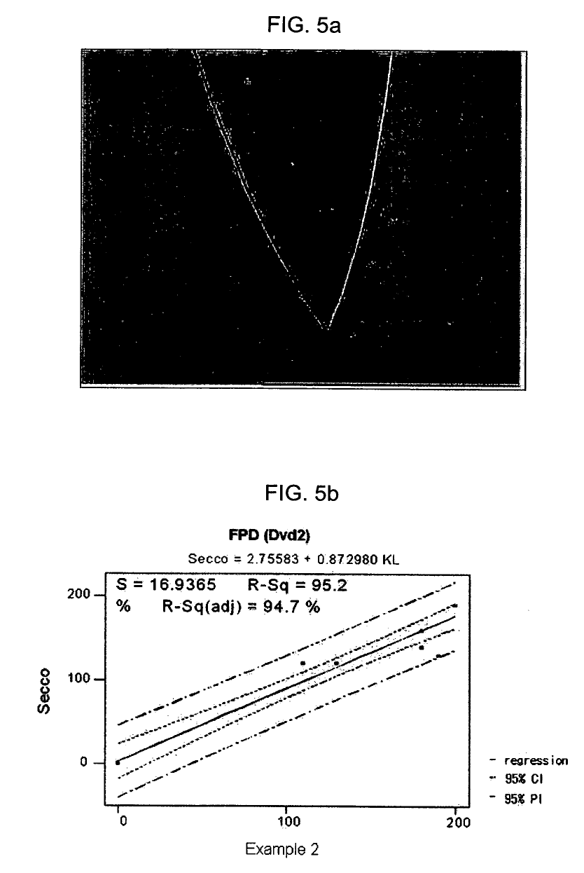

A silicon wafer was treated as in Example 2, except that a Secco etching solution (1:2 mixture of K₂Cr₂O₇ (0.15 M) solution and HF) was used instead of an etching solution of the present invention. The surface of the silicon wafer is shown in FIG. 5a.

FIG. 4b is a graph showing the relationship between FPD and density of the silicon wafers treated in Example 2 and Comparative Example 3 (Secco etchant), and FIG. 5a is a photograph showing the defect (FPD) of a silicon wafer treated in Comparative Example 3 (Secco etchant).

### Example 3

### Crystal Defect Evaluation Using an Etching Solution of the Present Invention

A silicon wafer was prepared from a single crystal having a specific resistance value of 12.0 Ω·cm, which was grown by the Czochralski method.

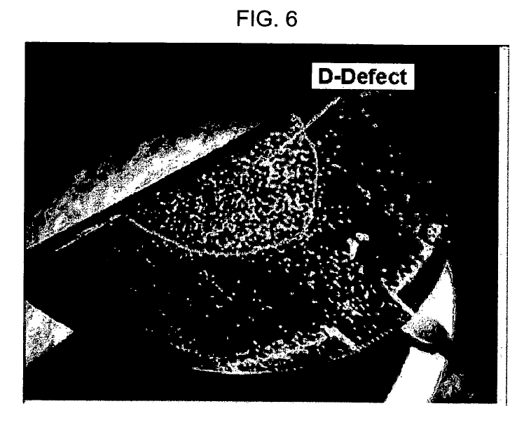

An etching solution of the present invention was prepared by mixing 3340 mL of 50% HF, 0.5 M KMnO₄, and 1650 mL of H₂O. The silicon wafer was treated with the etching solution at normal temperature and 1 atm for 90 seconds, without stirring. The surface of the silicon wafer is shown in FIG. 6.

Whereas the conventional analysis method treats the silicon wafer with the Secco etching solution for 30 minutes and the FPD defect is observed using a microscope, the evaluation method of the present invention can evaluate the D-defect much quicker (within 90 seconds) using an environmentally friendly etching solution that does not contain chromium.

As is apparent from the above description, the etching solutions for crystal defect evaluation of silicon wafers in accordance with the present invention can accurately and quickly evaluate crystal defects in silicon wafers having specific resistance values of 0.01 Ω·cm or smaller, which previously could only be evaluated by physical methods. Also, the etching solutions of the present invention can quickly evaluate D-defects in silicon wafers having specific resistance values exceeding 0.01 Ω·cm.

While the present invention has been described in detail with reference to certain exemplary embodiments, those skilled in the art will appreciate that various modifications and substitutions can be made to the described embodiments without departing from the spirit and scope of the present invention as set forth in the appended claims.

What is claimed is:

1. An etching solution for evaluating D-defects of a silicon wafer, the etching solution comprising KMnO₄, HF, and water.

2. The etching solution of claim 1, wherein the volume ratio of KMnO₄ to HF ranges from 0.5:1 to 1:3.

3. The etching solution of claim 1, wherein the etching solution is used to evaluate a crystal defect of a silicon wafer having a specific resistance value ranging from 0.005 Ω·cm to 0.01 Ω·cm.

4. The etching solution of claim 3, wherein the concentration of the KMnO₄ ranges from 0.3 M to 0.5 M.

5. The etching solution of claim 1, wherein the etching solution is used to evaluate a crystal defect of a silicon wafer having a specific resistance value ranging from 0.01 Ω·cm to 25.0 Ω·cm.

6. The etching solution of claim 5, wherein the concentration of KMnO₄ ranges from 0.4 M to 0.5 M.

7. The etching solution of claim 1, wherein the HF is 50% HF.

8. A method of evaluating a crystal defect of a silicon water, comprising:
surfacing the crystal defect by treating the silicon wafer with an etching solution comprising KMnO₄, HF and water; and
observing the defect with a microscope.

9. The method of claim 8, wherein the volume of KMnO₄ to HF in the etching solution ranges from 0.5:1 to 1:3.

10. The method of claim 8, wherein the concentration of KMnO₄ in the etching solution ranges from 0.3M to 0.5M.

11. The method of claim 8, wherein the concentration of KMnO₄ in the etching solution ranges from 0.4 M to 0.5M.

12. The method of claim 10, wherein the etching solution is used to evaluate a crystal defect of a silicon wafer having a specific resistance value ranging from 0.005 Ω·cm to 0.01 Ω·cm.

13. The method of claim 11, wherein the etching solution is used to evaluate a crystal defect of a silicon wafer having a specific resistance value ranging from 0.01 Ω·cm to 25.0 Ω·cm.

14. The method of claim 10, wherein the silicon wafer is treated with the etching solution for 20 to 60 seconds.

15. The method of claim 11, wherein the silicon wafer is treated with the etching solution for 45 to 90 seconds.
